(19) United States
(12) Patent Application Publication
(10) Pub. No.: US 2009/0098734 A1
(43) Pub. Date: Apr. 16, 2009

(54) METHOD OF FORMING SHALLOW TRENCH ISOLATION STRUCTURE AND METHOD OF POLISHING SEMICONDUCTOR STRUCTURE

(75) Inventor: Tzu-Yi Chuang, Kaohsiung County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/873,253

(22) Filed: Oct. 16, 2007

(51) Int. Cl. H01L 21/302

(52) U.S. Cl. 438/693; 257/E21.214

(57) ABSTRACT

A method of forming an STI structure is described. A patterned mask layer is formed over a substrate of a wafer. A portion of the substrate exposed by the patterned mask layer is removed to form trenches. A dielectric layer is formed over the substrate filling the trenches. A first CMP process is performed to remove a portion of the dielectric layer. A second CMP process is performed to remove a further portion of the dielectric layer and a portion of the patterned mask layer, such that the surface of the dielectric layer is lower than that of the patterned mask layer. The polishing rate in the second CMP process is lower than that in the first one. The polishing selectivity of the dielectric layer to the mask layer in the second CMP process is higher than that in the first one. The patterned mask layer is then removed.

### BACKGROUND OF THE INVENTION

1. Field of Invention

The present invention relates to a semiconductor process. More particularly, the present invention relates to a method of forming a shallow trench isolation (STI) structure and to a method of polishing a semiconductor structure.

2. Description of Related Art

With the advances in the semiconductor technology, the device dimension is reduced continuously. As the dimension is reduced to deep sub-micron or below, the possibility of short between adjacent devices is larger so that the device isolation issue becomes quite important. The isolation structure usually adopted in deep sub-micron processes is namely the STI structure. Because the performance and the reliability of the devices like leakage inhibition property largely depend on the quality of the STI structure, the STI process is a quite important part of a semiconductor process.

Conventionally, an STI structure is formed with a surface higher than that of the substrate, and there is a large height difference between the surfaces of the STI structure and the substrate. The height difference adversely affects the subsequent processes, so that the reliability of the resulting devices is lowered.

### SUMMARY OF THE INVENTION

Accordingly, this invention provides a method of forming an STI structure that is capable of reducing the height difference between the STI structure and the substrate.

This invention also provides a method of polishing a semiconductor structure, which is capable of improving the reliability of the corresponding device.

The method of forming an STI structure of this invention is described below. A patterned mask layer is formed on a substrate of a wafer, and then a portion of the substrate exposed by the patterned mask layer is removed to form trenches therein. A dielectric layer is formed over the substrate filling the trenches. A first CMP process is performed to remove a portion of the dielectric layer, and then a second CMP process is performed to remove a further portion of the dielectric layer and a portion of the patterned mask layer, such that the surface of the dielectric layer is lower than that of the patterned mask layer. The patterned mask layer is then removed. In this method, the polishing rate in the second CMP process is lower than that in the first CMP process, and the polishing selectivity of the dielectric layer to the mask layer in the second CMP process is higher than that in the first CMP process.

In an embodiment, the above method may further include a step of forming a pad layer on the substrate before the mask layer is formed and a step of removing the pad layer after the patterned mask layer is removed.

In an embodiment, a first polishing slurry used in the first CMP process is different from a second polishing slurry used in the second CMP process. The first polishing slurry may be an alumina (Al₂O₃) slurry. The second polishing slurry may be a dicerium trioxide (Ce₂O₃) slurry.

In an embodiment, the first CMP process and the second CMP process use the same polishing pad.

The method of polishing a semiconductor structure of this invention is described below. A semiconductor substrate with a first film and a second film sequentially formed thereon is provided. A first CMP process is performed to reduce the height difference between the highest point and the lowest point of the surface of the second film. A second CMP process is then performed, such that the surface of the second film is lower than that of the first film. In this method, the polishing rate in the second CMP process is lower than that in the first CMP process, and the polishing selectivity of the second film to the first film in the second CMP process is higher than that in the first CMP process.

In an embodiment, a first polishing slurry used in the first CMP process is different from a second polishing slurry used in the second CMP process. The first polishing slurry may be an alumina (Al₂O₃) slurry. The second polishing slurry may be a dicerium trioxide (Ce₂O₃) slurry.

In an embodiment, the first CMP process and the second CMP process use the same polishing pad.

In some embodiments, the first film may be a silicon nitride (SiN) film. The second film may be a silicon oxide (SiO) film.

As mentioned above, the method of forming an STI structure of this invention divides the CMP procedure of the STI dielectric layer into a first and a second CMP processes. The first CMP process has a relatively lower polishing selectivity but a relatively higher polishing rate to reduce the thickness difference between the central portion and the edge portion of the dielectric layer. The second CMP process makes the surface of the dielectric layer lower than that of the patterned mask layer, and has a relatively lower polishing rate but a relatively higher polishing selectivity so that the height difference between the STI structure and substrate is reduced.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A-1E illustrate a process flow of forming an STI structure according to an embodiment of this invention.

### DESCRIPTION OF EMBODIMENTS

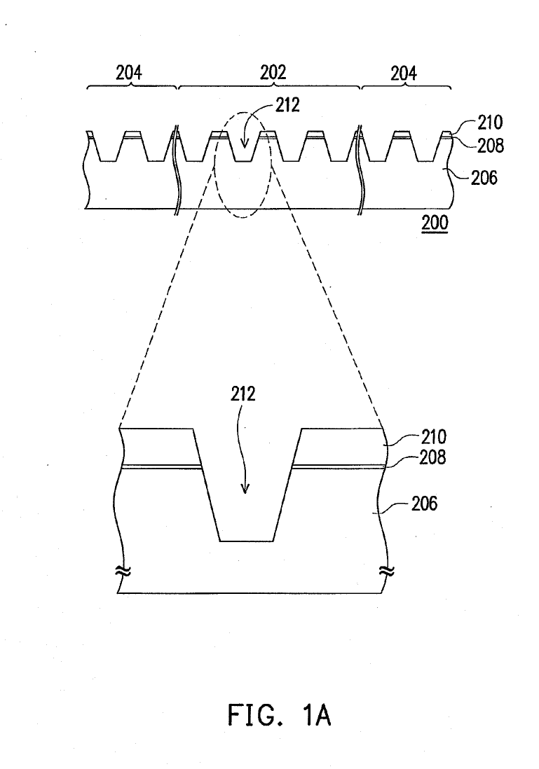

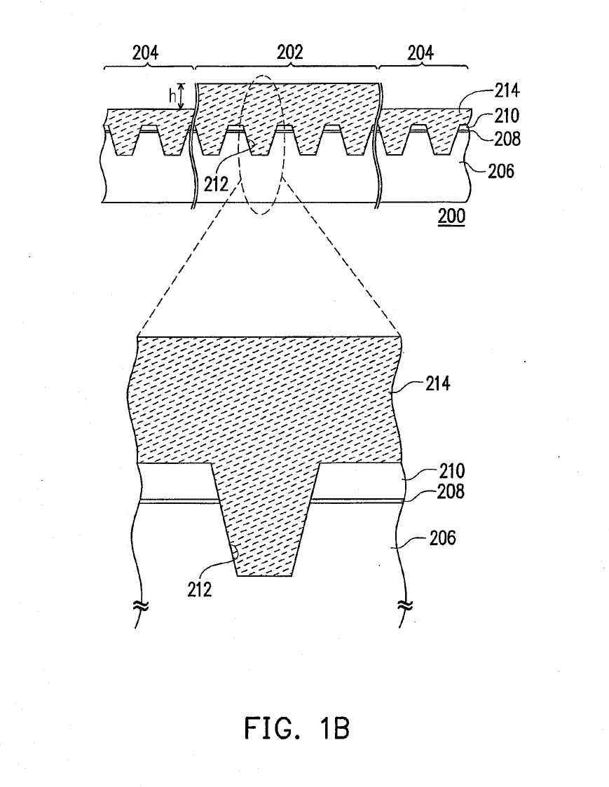

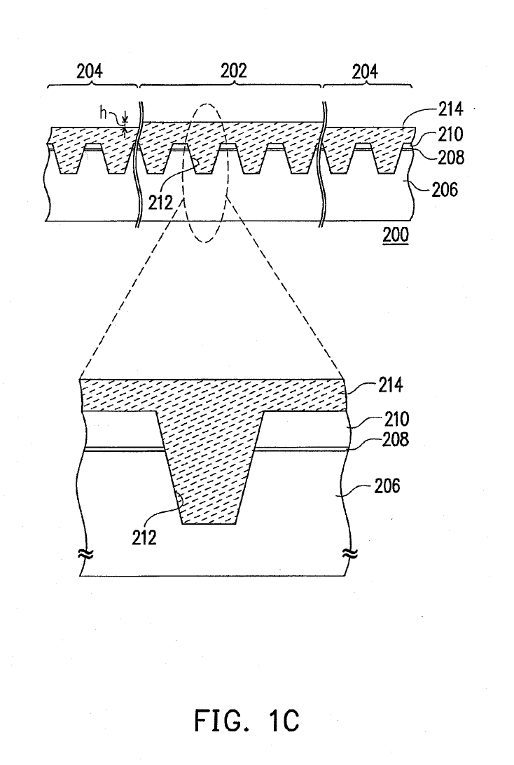

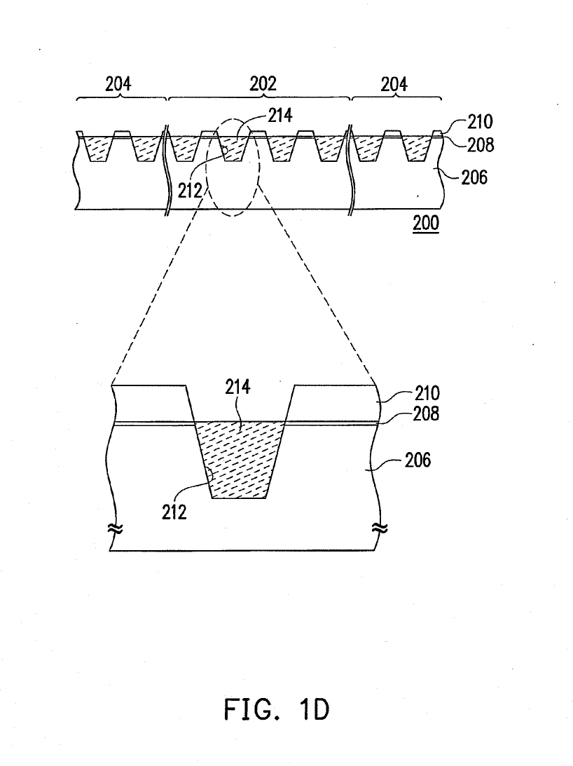

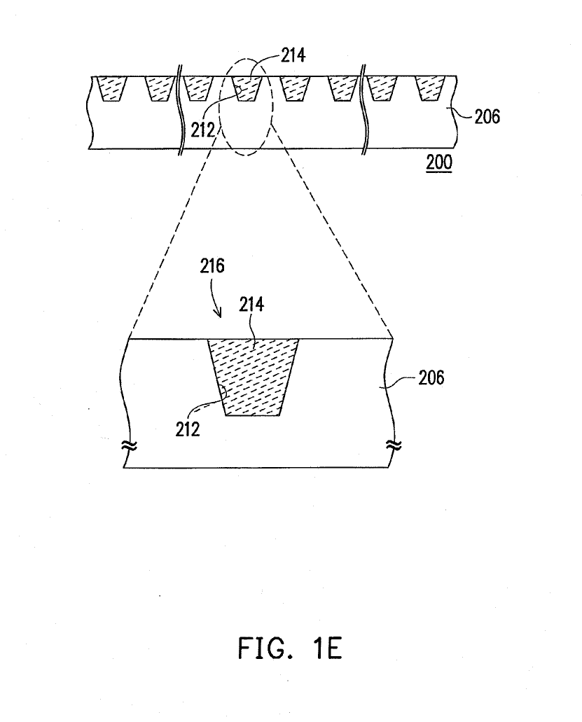

FIGS. 1A-1E illustrate a process flow of forming an STI structure according to an embodiment of this invention.

Referring to FIG. 1A first, a wafer 200 is provided including a semiconductor substrate 206 that includes a central area 202 and edge areas 204. A pad layer 208 and a patterned mask layer 210 are sequentially formed on the substrate 206 through, for example, the following steps. A layer of a pad material, a layer of a mask material and a patterned photoresist layer (not shown) are formed on the substrate 206 in sequence. The mask material and the pad material not covered by the patterned photoresist layer are etched away to expose a portion of the substrate 206, and then the photoresist layer is removed. The pad material may be silicon oxide (SiO), and may be formed through thermal oxidation. The mask material may be silicon nitride (SiN), and may be formed through low-pressure chemical vapor deposition (LPCVD).

Then, anisotropic etching is conducted using the patterned mask layer 210 as a mask to remove the exposed portion of the substrate 206 and form trenches 212 therein.

Referring to FIG. 1B, a dielectric layer 214 is formed over the substrate 206 filling the trenches 212. The dielectric layer 214 may include SiO, and may be formed through plasma-enhanced chemical vapor deposition (PECVD) or high-density plasma chemical vapor deposition (HDP-CVD).

In general, a dielectric layer 214 formed all over a wafer 200 does not have a uniform thickness. In some cases where the deposition rate at the central area 202 of the wafer 200 is larger than that at edge areas 204 of the wafer 200, the dielectric layer 214 is thicker at the central area 202 than at the edge area 204, as shown in FIG. 1B. The height difference between the highest point and the lowest point of the surface of the dielectric layer 214 is labeled with “h”. There are also a plenty of cases where the dielectric layer 214 is thicker at the edge areas 204 than at the central area 202. In the prior art, such an uneven surface of the dielectric layer 214 makes it difficult to form uniform STI structures.

Referring to FIG. 1C, a first CMP process is conducted to removed a portion of the dielectric layer 214, such that the dielectric thickness difference between the central area 202 and the edge areas 204 is reduced, i.e., the height difference “h” between the highest point and the lowest point of the surface of the dielectric layer 214 is reduced. The first CMP process is done with a polishing slurry that makes a relatively higher polishing rate but a relatively lower polishing selectivity of the dielectric layer 214 to the mask layer 210, for example, a polishing selectivity close to 1 from the larger side.

Since the first CMP process has a relatively lower polishing selectivity but a relatively higher polishing rate, the thicker portion of the dielectric layer 214 is thinned rapidly. Meanwhile, the uniformity of the total thickness of all films including the dielectric layer 214 is improved because the polishing selectivity of the dielectric layer 214 to the mask layer 210 is relatively lower.

Referring to FIG. 1D, a second CMP process is conducted to remove a further portion of the dielectric layer 214 and a portion of the patterned mask layer 210, such that the surface of the dielectric layer 214 is lower than that of the patterned mask layer 210. The polishing selectivity of the dielectric layer 214 to the mask layer 210 in the second CMP process is higher than that in the first CMP process, and the polishing rate in the second CMP process is lower than that in the first CMP process, so that the height of the resulting STI structure is controlled precisely.

In an embodiment, the first and second CMP processes use the same polishing pad. The difference in the polishing selectivity can be achieved by using different polishing slurries possibly different in the property of abrasive and/or the composition of polishing slurry. For example, it is possible that the first CMP process uses an alumina (Al₂O₃) slurry like the SS-25E slurry produced by the Cabbot Company while the second CMP process uses a dicerium trioxide (Ce₂O₃) slurry like the HSS slurry also produced by the Cabbot Company.

Referring to FIG. 1E, the patterned mask layer 210 and the pad layer 208 are removed to complete the fabricating process of the STI structure 216, possibly through isotropic etching.

Because the surface of the dielectric layer 214 is lower than that of the patterned mask layer 210 through the second CMP process, the height difference between the STI structure 216 and the substrate 206 is reduced as compared with the prior art so that the subsequent processes are less affected.

As mentioned above, the method of forming an STI structure of this invention divides the CMP procedure of the STI dielectric layer into a first and a second CMP processes. The first CMP process has a relatively lower polishing selectivity but a relatively higher polishing rate to reduce the thickness difference between the central portion and the edge portion of the dielectric layer. The second CMP process makes the surface of the dielectric layer lower than that of the patterned mask layer, and has a relatively lower polishing rate but a relatively higher polishing selectivity so that the height difference between the STI structure and substrate is reduced.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of forming a shallow trench isolation (STI) structure, comprising:
forming a patterned mask layer on a substrate of a wafer;
removing a portion of the substrate exposed by the patterned mask layer to form a plurality of trenches in the substrate;
forming over the substrate a dielectric layer filling the trenches;
performing a first CMP process to remove a portion of the dielectric layer;
performing a second CMP process to remove a further portion of the dielectric layer and a portion of the patterned mask layer, such that a surface of the dielectric layer is lower than a surface of the patterned mask layer, wherein a polishing rate in the second CMP process is lower than a polishing rate in the first CMP process, and a polishing selectivity of the dielectric layer to the mask layer in the second CMP process is higher than a polishing selectivity of the dielectric layer to the mask layer in the first CMP process; and
removing the patterned mask layer.

2. The method of claim 1, further comprising:
forming a pad layer on the substrate before the mask layer is formed; and
removing the pad layer after the patterned mask layer is removed.

3. The method of claim 1, wherein a first polishing slurry used in the first CMP process is different from a second polishing slurry used in the second CMP process.

4. The method of claim 3, wherein the first polishing slurry is an alumina (Al₂O₃) slurry.

5. The method of claim 3, wherein the second polishing slurry is a dicerium trioxide (Ce₂O₃) slurry.

6. The method of claim 3, wherein the first CMP process and the second CMP process use the same polishing pad.

7. A method of polishing a semiconductor structure, comprising:
providing a semiconductor substrate with a first film and a second film formed thereon in sequence;
performing a first CMP process to reduce height difference between a highest point and a lowest point of a surface of the second film; and
performing a second CMP process in a second polishing rate such that a surface of the second film is lower than a surface of the first film, wherein a polishing rate in the second CMP process is lower than a polishing rate in the first CMP process, and a polishing selectivity of the second film to the first film in the second CMP process is higher than a polishing selectivity of the second film to the first film in the first CMP process.

8. The method of claim 7, wherein a first polishing slurry used in the first CMP process is different from a second polishing slurry used in the second CMP process.

9. The method of claim 8, wherein the first polishing slurry is an alumina (Al₂O₃) slurry.

10. The method of claim 8, wherein the second polishing slurry is a dicerium trioxide (Ce₂O₃) slurry.

11. The method of claim 8, wherein the first CMP process and the second CMP process use the same polishing pad.

12. The method of claim 7, wherein the first film comprises a silicon nitride film.

13. The method of claim 7, wherein the second film comprises a silicon oxide film.
